(19) United States
(12) Patent Application Publication
(10) Pub. No.: US 2024/0097073 A1
(43) Pub. Date: Mar. 21, 2024

(54) DISPLAY DEVICE AND METHOD OF MANUFACTURING THE SAME

(71) Applicant: Samsung Display Co., LTD., Yongin-si (KR)

(72) Inventors: Dong Lim KIM, Yongin-si (KR); Won Hee NAM, Yongin-si (KR); Hang Jae LEE, Yongin-si (KR)

(73) Assignee: Samsung Display Co., LTD., Yongin-si (KR)

(21) Appl. No.: 18/316,582

(22) Filed: May 12, 2023

(30) Foreign Application Priority Data
Sep. 13, 2022 (KR) 10-2022-0115184

(51) Int. Cl. H01L 33/38; H01L 25/16

(52) U.S. Cl. CPC H01L 33/38; H01L 25/167; H01L 2933/0016

(57) ABSTRACT

A display device includes a first electrode and a second electrode spaced apart from each other, a third electrode and a fourth electrode intersecting the first and second electrodes and spaced apart from each other, and light emitting elements disposed between the first and second electrodes. A first end of each of the light emitting elements faces the third electrode, and a second end of each of the light emitting elements faces the fourth electrode.

### CROSS REFERENCE TO RELATED APPLICATION(S)

This application claims priority to and benefits of Korean Patent Application No. 10-2022-0115184 under 35 U.S.C. § 119, filed on Sep. 13, 2022, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

Recently, as interest in an information display is increasing, research and development for a display device are continuously being conducted.

### SUMMARY

An object to be solved by the disclosure is to provide a display device and a method of manufacturing the same capable of improving alignment of light emitting elements (e.g., an alignment degree of light emitting elements).

An object of the disclosure is not limited to the above-described object, and other technical objects which are not described will be clearly understood by those skilled in the art from the following description.

According to an embodiment of the disclosure for solving the above-described object, a display device includes a first electrode and a second electrode spaced apart from each other, a third electrode and a fourth electrode intersecting the first and second electrodes and spaced apart from each other, and light emitting elements disposed between the first and second electrodes. A first end of each of the light emitting elements faces the third electrode, and a second end of each of the light emitting elements faces the fourth electrode.

The first and second electrodes may be spaced apart from each other in a first direction and may extend in a second direction, and the third and fourth electrodes may be spaced apart from each other in the second direction and may extend in the first direction.

The light emitting elements may be arranged in the second direction.

The first and second electrodes may be disposed on the third and fourth electrodes.

The display device may further include an insulating layer between the first and second electrodes and the third and fourth electrodes.

The display device may further include a first connection electrode that is in electrical contact with the first end of each of the light emitting elements, and a second connection electrode that is in electrical contact with the second end of each of the light emitting elements.

The first connection electrode may be electrically connected to the first electrode, and the second connection electrode may be electrically connected to the second electrode.

The third and fourth electrodes may be disposed on the first and second electrodes.

The light emitting elements may be electrically connected to the third and fourth electrodes.

A side portion between the first end and the second end of each of the light emitting elements may face the first and second electrodes.

According to an embodiment of the disclosure for solving the above-described object, a method of manufacturing a display device includes firstly aligning light emitting elements between first alignment electrodes by applying a first alignment signal to the first alignment electrodes, and secondly aligning the light emitting elements by applying a second alignment signal to second alignment electrodes crossing the first alignment electrodes. The second alignment electrodes extend in a first direction and are spaced apart from each other in a second direction, and the light emitting elements are aligned in the second direction in the secondly aligning of the light emitting elements.

A frequency of the first alignment signal may be different from a frequency of the second alignment signal.

The second alignment electrodes may include a first sub-alignment electrode and a second sub-alignment electrode spaced apart from each other in the second direction, a first end of each of the light emitting elements may face the first sub-alignment electrode, and a second end of each of the light emitting elements may face the second sub-alignment electrode.

The first and second sub-alignment electrodes may be alternately arranged in the second direction.

A side portion between the first end and the second end of each of the light emitting elements may face the first alignment electrodes.

The method may further include forming connection electrodes on the light emitting elements.

The connection electrodes may be electrically connected to the first alignment electrodes.

The first alignment electrodes may be formed on the second alignment electrodes.

The connection electrodes may be electrically connected to the second alignment electrodes.

The second alignment electrodes may be formed on the first alignment electrodes.

Details of other embodiments are included in the detailed description and drawings.

According to the above-described embodiment, since a position and a direction of the light emitting elements may be precisely controlled by aligning the position of the light emitting elements by using the first alignment electrodes and aligning the direction of the light emitting elements by using the second alignment electrodes, an alignment degree of the light emitting elements may be improved.

An effect according to embodiments is not limited by the contents illustrated above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIGS. 2 and 3 are schematic diagrams of equivalent circuits each illustrating a sub-pixel according to an embodiment;

FIGS. 4 and 5 are schematic plan views each illustrating a sub-pixel according to an embodiment;

FIGS. 6 and 7 are schematic cross-sectional views taken along line A-A′ of FIG. 4;

FIG. 8 is a schematic cross-sectional view taken along line B-B′ of FIG. 4;

FIG. 9 is a schematic plan view illustrating a sub-pixel according to an embodiment;

FIG. 10 is a schematic cross-sectional view taken along line C-C′ of FIG. 9;

FIG. 11 is a schematic cross-sectional view taken along line D-D′ of FIG. 9;

FIGS. 12 and 13 are schematic cross-sectional views each illustrating a pixel unit according to an embodiment;

FIG. 14 is a schematic perspective view illustrating a light emitting element according to an embodiment;

FIG. 15 is a schematic cross-sectional view illustrating a light emitting element according to an embodiment; and

FIGS. 16 to 21 are schematic plan views for each process step of a method of manufacturing a display device according to an embodiment.

### DETAILED DESCRIPTION OF THE EMBODIMENTS

The advantages and features of the disclosure and a method of achieving them will become apparent with reference to the embodiments described in detail below together with the accompanying drawings. However, the disclosure is not limited to the embodiments disclosed below, and may be implemented in various different forms. The embodiments are provided so that the disclosure will be more thorough and complete and those skilled in the art to which the disclosure pertains can understand the scope of the disclosure.

The term used in the specification is for describing embodiments and is not intended to limit the disclosure. In the specification, the singular form also includes the plural form unless otherwise specified. The term “comprises” and/or “includes” does not exclude presence or addition of one or more other components, steps, operations, and/or elements to the described component, step, operation, and/or element.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements A case in which an element or a layer is referred to as “on” another element or layer includes a case in which another layer or another element is disposed directly on the other element or between the other layers. The same reference numerals denote to the same components throughout the specification.

Although a first, a second, and the like are used to describe various components, these components are not limited by these terms. These terms are used only to distinguish one component from another component. Therefore, a first component described below may be a second component within the technical spirit of the disclosure.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure are described in detail with reference to the accompanying drawings.

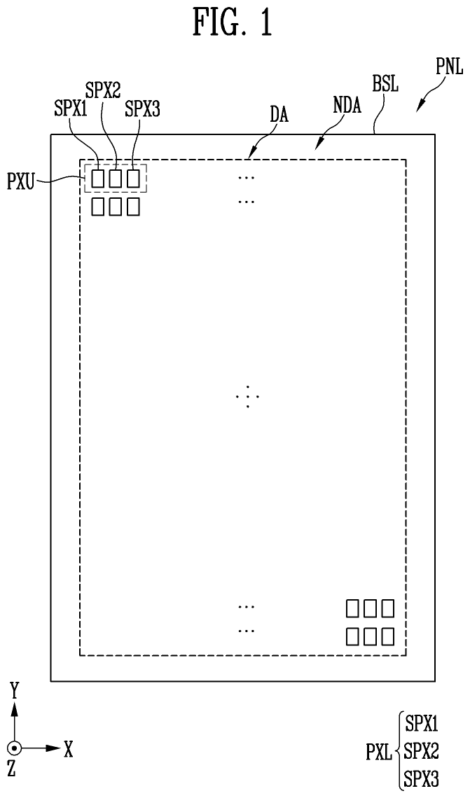

FIG. 1 is a schematic plan view illustrating a display device according to an embodiment. FIG. 1 shows a display panel PNL provided in the display device.

In FIG. 1, a structure of the display panel PNL is briefly shown based on a display area DA. However, according to an embodiment, at least one driving circuit unit (or driving circuit part) (for example, at least one of a scan driver and a data driver), lines, and/or pads, which are/is not shown, may be further disposed on the display panel PNL.

Referring to FIG. 1, the display panel PNL and a base layer BSL for forming the same may include the display area DA for displaying an image and a non-display area NDA that is not the display area DA. The display area DA may configure a screen on which the image is displayed, and the non-display area NDA may be a remaining area other than the display area DA.

A pixel unit (or pixel) PXU may be disposed in the display area DA. The pixel unit PXU may include a first sub-pixel SPX1, a second sub-pixel SPX2, and/or a third sub-pixel SPX3. Hereinafter, when at least one sub-pixel among the first sub-pixel SPX1, the second sub-pixel SPX2, and the third sub-pixel SPX3 is arbitrarily referred to, or when two or more types of sub-pixels are collectively referred to, the at least one sub-pixel or the two or more types of sub-pixels are referred to as a “sub-pixel SPX” or “sub-pixels SPX”.

The sub-pixels SPX may be regularly arranged according to a stripe or PENTILE™ arrangement structure, or the like. However, an arrangement structure of the sub-pixels SPX is not limited thereto, and the sub-pixels SPX may be arranged in the display area DA in various structures and/or methods.

According to an embodiment, two or more types of sub-pixels SPX emitting light of different colors may be disposed in the display area DA. For example, in the display area DA, the first sub-pixels SPX1 emitting light of a first color, the second sub-pixels SPX2 emitting light of a second color, and the third sub-pixels SPX3 emitting light of a third color may be arranged. At least one of the first to third sub-pixels SPX1, SPX2, and SPX3 disposed to be adjacent to each other may configure one pixel unit PXU capable of emitting light of various colors. For example, each of the first to third sub-pixels SPX1, SPX2, and SPX3 may be a sub-pixel emitting light of a predetermined color. According to an embodiment, the first sub-pixel SPX1 may be a red sub-pixel emitting red light, the second sub-pixel SPX2 may be a green sub-pixel emitting green light, and the third sub-pixel SPX3 may be a blue sub-pixel emitting blue light, but are not limited thereto.

In an embodiment, the first sub-pixel SPX1, the second sub-pixel SPX2, and the third sub-pixel SPX3 may include light emitting elements that emit light of the same color, and may include a color conversion layer and/or a color filter layer of different colors disposed on the respective light emitting elements, to emit light of the first color, the second color, and the third color, respectively. In another embodiment, the first sub-pixel SPX1, the second sub-pixel SPX2, and the third sub-pixel SPX3 may include a light emitting element of the first color, a light emitting element of the second color, and a light emitting element of the third color as a light source, to emit light of the first color, the second color, and the third color, respectively. However, a color, a type, the number, and/or the like of the sub-pixels SPX configuring each pixel unit PXU are/is not particularly limited. That is a color of light emitted by each sub-pixel SPX may be variously changed.

The sub-pixel SPX may include at least one light source driven by a control signal (for example, a scan signal and a data signal) and/or power (for example, first power and second power). In an embodiment, the light source may include at least one light emitting element, for example, ultra-small column shape light emitting elements having a size as small as a nanometer scale to a micrometer scale. However, the disclosure is not limited thereto, and various types of light emitting elements may be used as the light source of the sub-pixel SPX.

In an embodiment, each sub-pixel SPX may be configured as an active sub-pixel. However, a type, a structure, and/or a driving method of the sub-pixels SPX applicable to the display device are/is not particularly limited. For example, each sub-pixel SPX may be configured as a sub-pixel of a passive or active light emitting display device of various structures and/or driving methods.

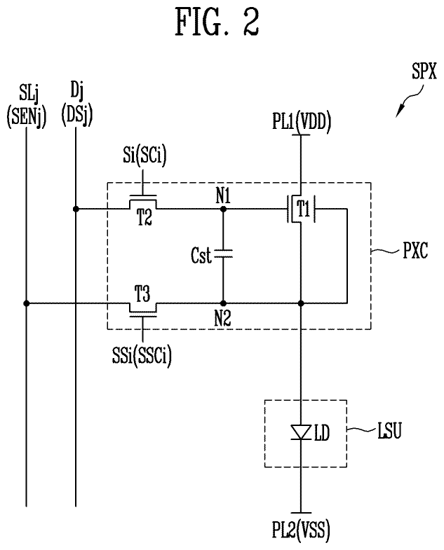

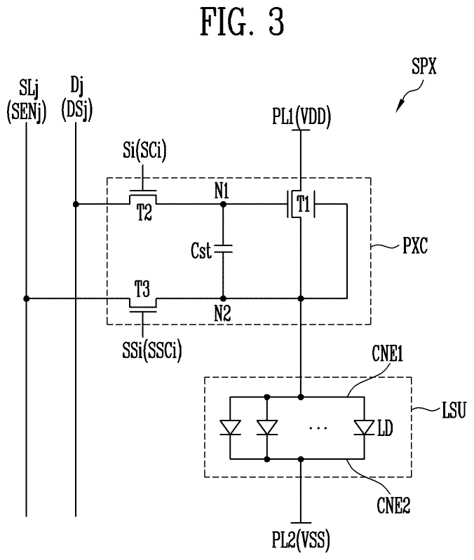

FIGS. 2 and 3 are schematic diagrams of equivalent circuits each illustrating a sub-pixel according to an embodiment.

According to an embodiment, the sub-pixel SPX shown in FIGS. 2 and 3 may be any one of the first sub-pixel SPX1, the second sub-pixel SPX2, and the third sub-pixel SPX3 provided in the display panel PNL of FIG. 1. The first sub-pixel SPX1, the second sub-pixel SPX2, and the third sub-pixel SPX3 may have structures substantially identical or similar to each other.

Referring to FIGS. 2 and 3, the sub-pixel SPX may include a light source unit (or light source part) LSU for generating light of a luminance corresponding to a data signal, and a pixel circuit PXC for driving the light source unit LSU.

The light source unit LSU may include at least one light emitting element LD electrically connected between first power VDD and second power VSS. The first power VDD and the second power VSS may have different potentials so that the light emitting element LD emits light. For example, the first power VDD may be set as high potential power, and the second power VSS may be set as low potential power. A potential difference between the first power VDD and the second power VSS may be set to be substantially equal to or greater than a threshold voltage of the light emitting element LD during at least an emission period of the sub-pixel SPX.

The light emitting element LD may emit light with a luminance corresponding to a driving current supplied through the pixel circuit PXC. The light emitting element LD may be configured of an organic light emitting diode, or an inorganic light emitting diode such as a micro light emitting diode or a quantum dot light emitting diode. In an embodiment, the light emitting element LD may be a light emitting diode of an ultra-small size, for example, a size as small as a nanometer scale to a micrometer scale, including a material of an inorganic crystal structure.

In an embodiment, the light source unit LSU may include light emitting elements LD connected in parallel to each other. As shown in FIG. 3, the light source unit LSU may include a first connection electrode CNE1 electrically connected to the first power VDD via the pixel circuit PXC and a first power line PL1, a second connection electrode CNE2 electrically connected to the second power VSS through a second power line PL2, and the light emitting elements LD electrically connected in the same direction between the first and second connection electrodes CNE1 and CNE2. In an embodiment, the first connection electrode CNE1 may be an anode electrode or may correspond to the anode electrode, and the second connection electrode CNE2 may be a cathode electrode or may correspond to the cathode electrode.

The light emitting element LD may include a first end (for example, a p-type end) electrically connected to the first power VDD through the first connection electrode CNE1 and/or the pixel circuit PXC, and a second end (for example, an n-type end) electrically connected to the second power VSS through the second connection electrode CNE2. For example, the light emitting element LD may be connected in parallel in a forward direction between the first and second connection electrodes CNE1 and CNE2. Each of the light emitting elements LD connected in the forward direction between the first power VDD and the second power VSS may configure each effective light source, and the effective light sources may be collected to configure the light source unit LSU of the sub-pixel SPX.

The first end of the light emitting element LD may be commonly connected to the pixel circuit PXC through one electrode (for example, the first connection electrode CNE1) of the light source unit LSU, and may be electrically connected to the first power VDD through the pixel circuit PXC and the first power line PL1. The second end of the light emitting element LD may be commonly connected to the second power VSS through another electrode (for example, the second connection electrode CNE2) of the light source unit LSU and the second power line PL2.

According to an embodiment, the light source unit LSU may include light emitting elements LD connected in series. The light source unit LSU may include at least one series stage. Each series stage may include a pair of electrodes (for example, two electrodes) and at least one light emitting element LD connected in a forward direction between the pair of electrodes. Here, the number of series stages configuring the light source unit LSU and the number of light emitting elements LD configuring each series stage are not particularly limited. For example, the number of light emitting elements LD configuring each series stage may be the same as or different from each other, and the number of light emitting elements LD is not particularly limited.

In case that the light emitting elements LD are connected in a series/parallel structure, power efficiency may be improved compared to a case where the same number of light emitting elements LD are connected only in parallel. In the sub-pixel SPX in which the light emitting elements LD are connected in the series/parallel structure, even if a short defect or the like occurs in some series stages, since a luminance may be expressed through the light emitting elements LD of remaining series stages, a dark spot defect possibility of the sub-pixel SPX may be reduced. However, the disclosure is not limited thereto, and the light source unit LSU may be configured by connecting the light emitting elements LD only in series, or the light source unit LSU may be configured by connecting the light emitting elements LD only in parallel.

The pixel circuit PXC may be electrically connected between the first power VDD and the light source unit LSU. The pixel circuit PXC may be electrically connected to a scan line Si (or a gate line) and a data line Dj. The pixel circuit PXC may be further electrically connected to a sensing control line SSi and a sensing line SLj. For example, in case that the sub-pixel SPX is disposed on an i-th (i is a natural number) horizontal line (row, or sub-pixel row) and a j-th (j is a natural number) vertical line (column, or sub-pixel column) of the display area DA, the pixel circuit PXC of the sub-pixel SPX may be electrically connected to an i-th scan line Si, an i-th sensing control line SSi, a j-th data line Dj, and the sensing line SLj of the display area DA.

According to an embodiment, the pixel circuit PXC may include transistors and at least one capacitor. For example, the pixel circuit PXC may include a first transistor T1, a second transistor T2, a third transistor T3, and a storage capacitor Cst.

The first transistor T1 may be electrically connected between the first power VDD and the light source unit LSU. For example, a first electrode (for example, a drain electrode) of the first transistor T1 may be electrically connected to the first power VDD, and a second electrode (for example, a source electrode) of the first transistor T1 may be electrically connected to one electrode (for example, the anode electrode) of the light source unit LSU. A gate electrode of the first transistor T1 may be electrically connected to a first node N1. A back gate electrode of the first transistor T1 may be electrically connected to a second node N2. The first transistor T1 may control the driving current supplied to the light source unit LSU in response to a voltage of the first node N1. For example, the first transistor T1 may be a driving transistor that controls the driving current of the sub-pixel SPX.

The second transistor T2 may be electrically connected between the data line Dj and the first node N1. For example, a first electrode (for example, a source electrode) of the second transistor T2 may be electrically connected to the data line Dj, and a second electrode (for example, a drain electrode) of the second transistor T2 may be electrically connected to the first node N1. A gate electrode of the second transistor T2 may be electrically connected to the scan line Si. The second transistor T2 may be turned on in case that a scan signal SCi of a gate-on voltage (for example, a high level voltage) is supplied from the scan line Si, to electrically connect the data line Dj and the first node N1. In each frame period, a data signal DSj of a corresponding frame may be supplied to the data line Dj, and the data signal DSj may be transferred to the first node N1 through the second transistor T2 turned on during a period in which the scan signal SCi of the gate-on voltage is supplied. For example, the second transistor T2 may be a switching transistor for transferring each data signal DSj to an inside of the sub-pixel SPX.

The third transistor T3 may be electrically connected between the first transistor T1 and the sensing line SLj. For example, a first electrode of the third transistor T3 may be electrically connected to the sensing line SLj, and a second electrode of the third transistor T3 may be electrically connected to the second node N2 (or the second electrode of the first transistor T1). A gate electrode of the third transistor T3 may be connected to the sensing control line SSi. In case that the sensing control line SSi is omitted, the gate electrode of the third transistor T3 may be connected to the scan line Si (a previous scan line positioned in a row previous to the scan line Si or a subsequent scan line positioned in a row subsequent to the scan line Si). The third transistor T3 may be turned on by a sensing control signal SSCi of a gate-on voltage supplied to the sensing control line SSi during a sensing period, to electrically connect the sensing line SLj and the first transistor T1.

According to an embodiment, the sensing period may be a period in which a characteristic (for example, a threshold voltage or the like of the first transistor T1) of the sub-pixel SPX disposed in the display area DA is extracted. During the sensing period, a reference voltage at which the first transistor T1 may be turned on may be supplied to the first node N1 through the data line Dj and the second transistor T2, or each sub-pixel SPX may be connected to a current source or the like, to turn on the first transistor T1. Since the third transistor T3 is turned on by supplying the sensing control signal SSCi of the gate-on voltage to the third transistor T3, the first transistor T1 may be electrically connected to the sensing line SLj. Thereafter, a sensing signal SENj may be output to an external device through the sensing line SLj, and the characteristics of each sub-pixel SPX including the threshold voltage or the like of the first transistor T1 may be detected by using the sensing signal SENj.

A first electrode of the storage capacitor Cst may be electrically connected to the second node N2, and a second electrode of the storage capacitor Cst may be electrically connected to the first node N1. The storage capacitor Cst may be charged with a voltage corresponding to the data signal DSj supplied to the first node N1 during each frame period.

In FIGS. 2 and 3, all transistors included in the pixel circuit PXC, for example, the first to third transistors T1, T2, and T3 are N-type transistors, but the disclosure is not limited thereto. At least one of the first to third transistors T1, T2, and T3 may be changed to a P-type transistor. In addition, the pixel circuit PXC may be configured of a pixel circuit of various structures and/or driving methods.

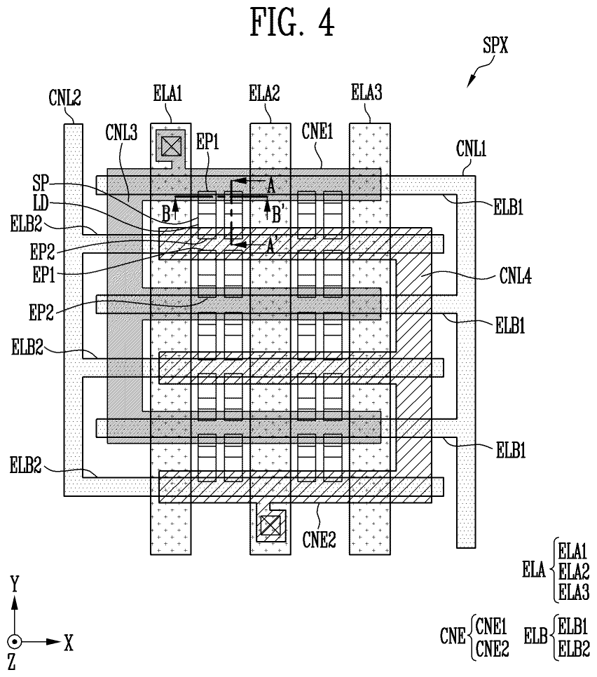

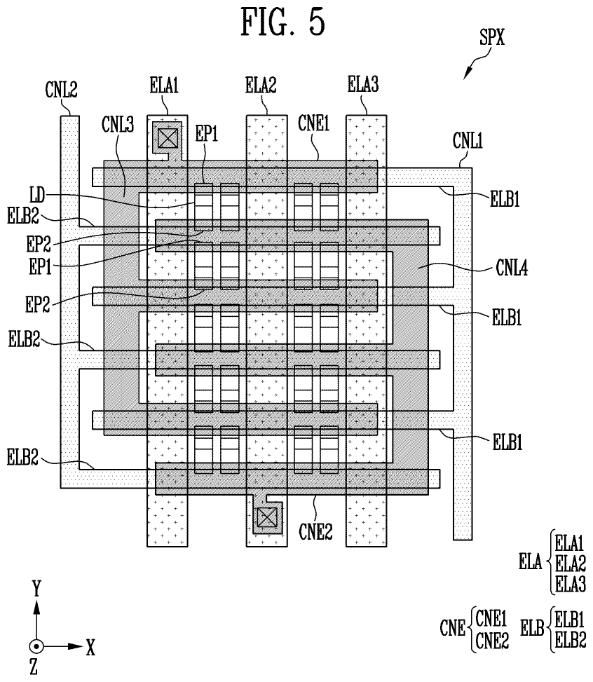

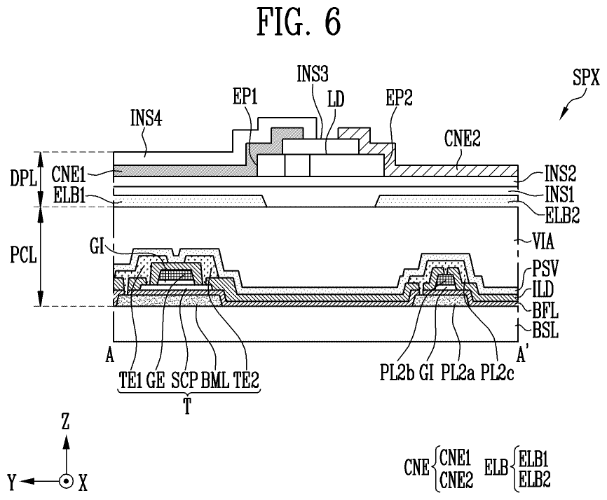

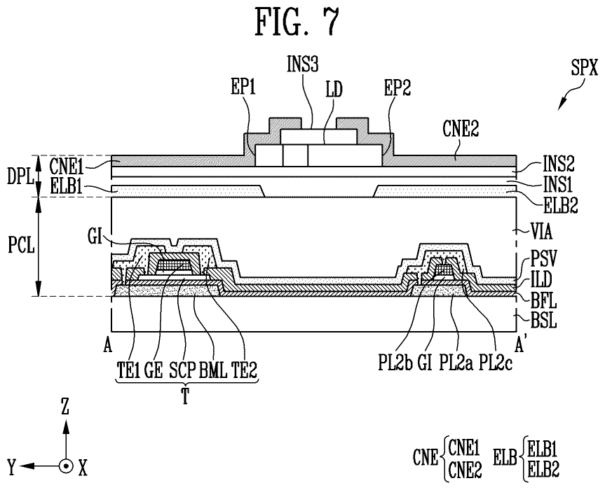

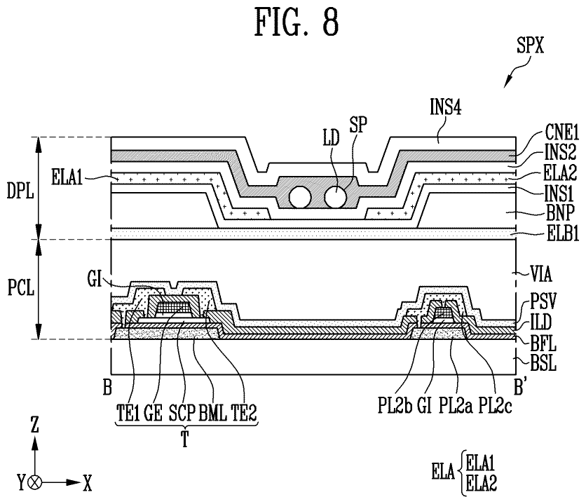

FIGS. 4 and 5 are schematic plan views each illustrating a sub-pixel according to an embodiment. FIGS. 6 and 7 are cross-sectional views taken along line A-A′ of FIG. 4. FIG. 8 is a cross-sectional view taken along line B-B′ of FIG. 4.

For example, FIGS. 4 and 5 may be any one of the first to third sub-pixels SPX1, SPX2 and SPX3 configuring the pixel unit PXU of FIG. 1, and the first to third sub-pixels SPX1, SPX2, and SPX3 may have structures identical or similar to each other.

Referring to FIGS. 4 and 5, the sub-pixel SPX may include first alignment electrodes ELA, second alignment electrodes ELB, the light emitting elements LD, and/or connection electrodes CNE.

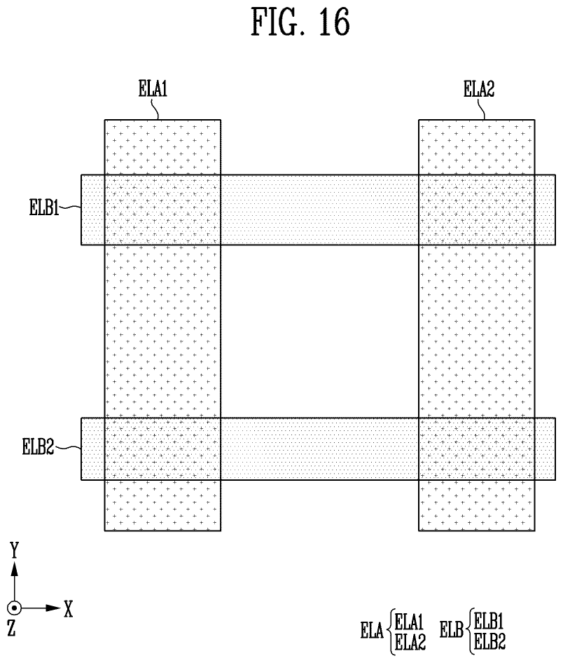

The first alignment electrodes ELA may extend in a second direction (Y-axis direction) and may be spaced apart from each other in a first direction (X-axis direction). The first alignment electrodes ELA may include a first alignment line ELA1, a second alignment line ELA2, and a third alignment line ELA3 spaced apart from each other. The second alignment line ELA2 may be disposed between the first alignment line ELA1 and the third alignment line ELA3. The first alignment line ELA1, the second alignment line ELA2, and the third alignment line ELA3 may be sequentially arranged along the first direction (X-axis direction). The first alignment electrodes ELA may receive a first alignment signal in a step of aligning a position of the light emitting elements LD. For example, the first alignment electrodes ELA may function as alignment electrodes for aligning a position of the light emitting elements LD. A detailed description thereof is described below with reference to FIGS. 16 to 21.

A portion of the first alignment electrodes ELA may be connected to the pixel circuit PXC of FIG. 2 and/or a power line through a contact hole. For example, the first alignment line ELA1 may be connected to the pixel circuit PXC and/or the first power line PL1 through a contact hole, and the second alignment line ELA2 may be connected to the second power line PL2 through a contact hole, but the disclosure is not limited thereto.

The second alignment electrodes ELB may extend in the first direction (X-axis direction) and may be spaced apart from each other in the second direction (Y-axis direction). The second alignment electrodes ELB may cross (or intersect) the first alignment electrodes ELA. In the drawing, a case where the first alignment electrodes ELA extend in the second direction (Y-axis direction) and the second alignment electrodes ELB extend in the first direction (X-axis direction) to cross each other is illustrated, but an extension direction of the first alignment electrodes ELA and the second alignment electrodes ELB, an angle at which the first alignment electrodes ELA and the second alignment electrodes ELB cross each other, or the like may be variously changed in consideration of an arrangement of the light emitting elements LD in the sub-pixel SPX.

The second alignment electrodes ELB may receive a second alignment signal in a step of aligning a direction of the light emitting elements LD. For example, the second alignment electrodes ELB may function as direction alignment electrodes for aligning the direction of the light emitting elements LD. A detailed description thereof is described below with reference to FIGS. 16 to 21.

The second alignment electrodes ELB may include first sub-alignment electrodes ELB1 and second sub-alignment electrodes ELB2 spaced apart from each other. The first sub-alignment electrodes ELB1 and the second sub-alignment electrodes ELB2 may be alternately arranged in the second direction (Y-axis direction).

The first sub-alignment electrodes ELB1 may be connected to each other by a first connection line CNL1, and the second sub-alignment electrodes ELB2 may be connected to each other by a second connection line CNL2. The first connection line CNL1 and the second connection line CNL2 may extend in the second direction (Y-axis direction). The first connection line CNL1 may be integrally formed with (or integral with) the first sub-alignment electrodes ELB1, but is not limited thereto. The second connection line CNL2 may be integrally formed with the second sub-alignment electrodes ELB2, but is not limited thereto.

The light emitting elements LD may be positioned between the first alignment electrodes ELA. For example, the light emitting elements LD may be positioned between the first alignment line ELA1 and the second alignment line ELA2, and between the second alignment line ELA2 and the third alignment line ELA3. The light emitting elements LD may be arranged in the second direction (Y-axis direction) between the first alignment electrodes ELA.

The light emitting elements LD may be biasedly aligned between the second alignment electrodes ELB. For example, a first end EP1 of the light emitting elements LD may face the first sub-alignment electrode ELB1. A second end EP2 of the light emitting elements LD may face the second sub-alignment electrode ELB2. A side portion SP between the first end EP1 and the second end EP2 of the light emitting elements LD may face the first alignment electrodes ELA. Since the position and the direction of the light emitting elements LD may be precisely controlled by aligning the position of the light emitting elements LD by using the first alignment electrodes ELA and aligning the direction of the light emitting elements LD by using the second alignment electrodes ELB as described above, an alignment degree of the light emitting elements LD may be improved.

The light emitting elements LD may be electrically connected to the connection electrodes CNE. The connection electrodes CNE may extend in the first direction (X-axis direction) and may be spaced apart from each other in the second direction (Y-axis direction). The connection electrodes CNE may include first connection electrodes CNE1 and second connection electrodes CNE2 spaced apart from each other. The first connection electrodes CNE1 and the second connection electrodes CNE2 may be alternately arranged in the second direction (Y-axis direction). The first connection electrode CNE1 may overlap the first end EP1 of the light emitting elements LD and may be electrically connected to the first end EP1 of the light emitting elements LD. The second connection electrode CNE2 may overlap the second end EP2 of the light emitting elements LD and may be electrically connected to the second end EP2 of the light emitting elements LD.

According to an embodiment, the first connection electrode CNE1 may overlap the first alignment line ELA1 and may be electrically connected to the first alignment line ELA1 through a contact hole. The second connection electrode CNE2 may overlap the second alignment line ELA2 and may be electrically connected to the second alignment line ELA2 through a contact hole. Accordingly, the first connection electrode CNE1 may electrically connect the light emitting elements LD and the first alignment line ELA1, and the second connection electrode CNE2 may electrically connect the light emitting elements LD and the second alignment line ELA2. According to an embodiment, the first connection electrode CNE1 may be electrically connected to the first alignment line ELA1 through a first bridge electrode, and the second connection electrode CNE2 may be electrically connected to the second alignment line ELA2 through a second bridge electrode.

The connection electrodes CNE may be formed of (or include) conductive layers. As shown in FIG. 4, the first connection electrode CNE1 may be formed of a first conductive layer, and the second connection electrode CNE2 may be formed of a second conductive layer. As another example, as shown in FIG. 5, the first connection electrode CNE1 and the second connection electrode CNE2 may be formed of the same conductive layer. As described above, in case that the first connection electrode CNE1 and the second connection electrode CNE2 are formed of the same conductive layer, the number of masks may be reduced and a manufacturing process may be simplified.

According to an embodiment, the first connection electrodes CNE1 may be connected to each other by a third connection line CNL3. The second connection electrodes CNE2 may be connected to each other by a fourth connection line CNL4. The third connection line CNL3 and the fourth connection line CNL4 may extend in the second direction (Y-axis direction). The first connection electrodes CNE1 may be integrally formed with the third connection line CNL3, but are not limited thereto. The second connection electrodes CNE2 may be integrally formed with the fourth connection line CNL4, but are not limited thereto.

Hereinafter, a cross-sectional structure of the sub-pixel SPX is described in detail with reference to FIGS. 6 to 8. In FIGS. 6 to 8, the cross-sectional structure of the sub-pixel SPX is schematically shown based on the first alignment line ELA1 (or a first electrode) and the second alignment line ELA2 (or a second electrode) of the first alignment electrode ELA, and the first sub-alignment electrode ELB1 (or a third electrode) and the second sub-alignment electrode ELB2 (or a fourth electrode) of the second alignment electrode ELB. In addition, in FIGS. 6 to 8, the first transistor T1 among various circuit elements configuring the pixel circuit PXC of FIG. 2 is shown, and in case that the first to third transistors T1, T2, and T3 are not required to separately specify, the first to third transistors T1, T2, and T3 are referred to as a “transistor T”. Meanwhile, a structure, a position of each layer, and/or the like of the transistors T are/is not limited to the embodiment shown in FIGS. 6 to 8, and may be variously changed according to an embodiment.

The sub-pixels SPX according to an embodiment may include a pixel circuit layer PCL disposed on a base layer BSL and a display element layer DPL disposed on the pixel circuit layer PCL.

The base layer BSL may configure a base member and may be a rigid or flexible substrate or film. For example, the base layer BSL may be a rigid substrate formed of glass or tempered glass, a flexible substrate (or thin film) of a plastic or metal material, or at least one layer of insulating layer. A material and/or a physical property of the base layer BSL are/is not particularly limited. In an embodiment, the base layer BSL may be transparent. Here, transparent may mean that light may be transmitted at a transmittance or more. In another embodiment, the base layer BSL may be translucent or opaque. The base layer BSL may include a reflective material according to an embodiment.

The pixel circuit layer PCL may be disposed on the base layer BSL. A lower conductive layer BML and a first power conductive layer PL2a may be disposed on the base layer BSL. The lower conductive layer BML and the first power conductive layer PL2a may be disposed on the same layer. For example, the lower conductive layer BML and the first power conductive layer PL2a may be simultaneously formed in the same process, but are not limited thereto. The first power conductive layer PL2a may configure the second power line PL2 described with reference to FIG. 2 or the like.

Each of the lower conductive layer BML and the first power conductive layer PL2a may be formed as a single layer or multiple layers formed of molybdenum (Mo), copper (Cu), aluminum (Al), chromium (Cr), gold (Au), titanium (Ti), nickel (Ni), neodymium (Nd), indium (In), tin (Sn), and an oxide or an alloy thereof.

A buffer layer BFL may be disposed on the lower conductive layer BML and the first power conductive layer PL2a. The buffer layer BFL may prevent an impurity from diffusing into a circuit element. The buffer layer BFL may be configured as a single layer, but may be configured as multiple layers of at least double or more layers. In case that the buffer layer BFL is formed as multiple layers, each layer may be formed of the same material, or at least some layer(s) may be formed of different materials.

A semiconductor pattern SCP may be disposed on the buffer layer BFL. For example, each semiconductor pattern SCP may include a first region that is in contact with a first transistor electrode TE1, a second region that is in contact with a second transistor electrode TE2, and a channel region positioned between the first and second regions. According to an embodiment, one of the first and second regions may be a source region and the other may be a drain region.

According to an embodiment, the semiconductor pattern SCP may be formed of polysilicon, amorphous silicon, oxide semiconductor, or the like. The channel region of the semiconductor pattern SCP may be an intrinsic semiconductor as a semiconductor pattern which is not doped with an impurity, and each of the first and second regions of the semiconductor pattern SCP may be a semiconductor doped with an impurity.

A gate insulating layer GI may be disposed on the buffer layer BFL and the semiconductor pattern SCP. For example, the gate insulating layer GI may be disposed between the semiconductor pattern SCP and the gate electrode GE. The gate insulating layer GI may be disposed between the buffer layer BFL and a second power conductive layer PL2b. The gate insulating layer GI may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A gate electrode GE of the transistor T and the second power conductive layer PL2b may be disposed on the gate insulating layer GI. The gate electrode GE and the second power conductive layer PL2b may be disposed on the same layer. For example, the gate electrode GE and the second power conductive layer PL2b may be simultaneously formed in the same process, but are not limited thereto. The gate electrode GE may be disposed to overlap the semiconductor pattern SCP in a third direction (Z-axis direction) on the gate insulating layer GI. The second power conductive layer PL2b may be disposed to overlap the first power conductive layer PL2a in the third direction (Z-axis direction) on the gate insulating layer GI. The second power conductive layer PL2b may configure the second power line PL2, which is described with reference to FIG. 2 or the like, together with the first power conductive layer PL2a.

Each of the gate electrode GE and the second power conductive layer PL2b may be formed as a single layer or multiple layers formed of (or include) molybdenum (Mo), copper (Cu), aluminum (Al), chromium (Cr), gold (Au), titanium (Ti), nickel (Ni), neodymium (Nd), indium (In), tin (Sn), or an oxide or an alloy thereof. For example, each of the gate electrode GE and the second power conductive layer PL2b may be formed of multiple layers in which titanium (Ti), copper (Cu), and/or indium tin oxide (ITO) are/is sequentially or repeatedly stacked.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and a third power conductive layer PL2c.

The interlayer insulating layer ILD may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The first and second transistor electrodes TE1 and TE2 of the transistor T and the third power conductive layer PL2c may be disposed on the interlayer insulating layer ILD. The first and second transistor electrodes TE1 and TE2 and the third power conductive layer PL2c may be disposed on the same layer. For example, the first and second transistor electrodes TE1 and TE2 and the third power conductive layer PL2c may be simultaneously formed in the same process, but are not limited thereto.

The first and second transistor electrodes TE1 and TE2 may be disposed to overlap the semiconductor pattern SCP in the third direction (Z-axis direction). The first and second transistor electrodes TE1 and TE2 may be electrically connected to the semiconductor pattern SCP. For example, the first transistor electrode TE1 may be electrically connected to the first region of the semiconductor pattern SCP through a contact hole passing through the interlayer insulating layer ILD. The first transistor electrode TE1 may be electrically connected to the lower conductive layer BML through a contact hole passing through the interlayer insulating layer ILD and the buffer layer BFL. The second transistor electrode TE2 may be electrically connected to the second region of the semiconductor pattern SCP through a contact hole passing through the interlayer insulating layer ILD. According to an embodiment, any one of the first and second transistor electrodes TE1 and TE2 may be a source electrode, and the other may be a drain electrode.

The third power conductive layer PL2c may be disposed to overlap the first power conductive layer PL2a and/or the second power conductive layer PL2b in the third direction (Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole passing through the interlayer insulating layer ILD and the buffer layer BFL. The third power conductive layer PL2c may be electrically connected to the second power conductive layer PL2b through a contact hole passing through the interlayer insulating layer ILD. The third power conductive layer PL2c may configure the second power line PL2, which is described with reference to FIG. 2 or the like, together with the first power conductive layer PL2a and/or the second power conductive layer PL2b.

The first and second transistor electrodes TE1 and TE2 and the third power conductive layer PL2c may be formed as a single layer or multiple layers formed of molybdenum (Mo), copper (Cu), aluminum (Al), chromium (Cr), gold (Au), titanium (Ti), nickel (Ni), neodymium (Nd), indium (In), tin (Sn), and an oxide or an alloy thereof.

A protective layer PSV may be disposed on the first and second transistor electrodes TE1 and TE2 and the third power conductive layer PL2c. The protective layer PSV may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A via layer VIA may be disposed on the protective layer PSV. The via layer VIA may be formed of an organic material to planarize a lower step difference. For example, the via layer VIA may include an organic material such as acrylates resin, epoxy resin, phenolic resin, polyamides resin, polyimides resin, polyester resin, polyphenylenesulfides resin, or benzocyclobutene (BCB). However, the disclosure is not limited thereto, and the via layer VIA may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The display element layer DPL may be disposed on the via layer VIA. The second alignment electrodes ELB may be disposed on the via layer VIA. The second alignment electrodes ELB may be spaced apart from each other. The second alignment electrodes ELB may be disposed on the same layer. For example, the second alignment electrodes ELB may be simultaneously formed in the same process, but are not limited thereto.

The second alignment electrodes ELB may receive the second alignment signal in a direction alignment step of the light emitting elements LD. Accordingly, an electric field may be formed between the second alignment electrodes ELB, and thus the light emitting elements LD provided to each of the sub-pixels SPX may be biasedly aligned between the second alignment electrodes ELB.

The second alignment electrodes ELB may include at least one conductive material. For example, the second alignment electrodes ELB may include at least one conductive material among at least one metal among various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), or copper (Cu), an alloy including the same, a conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but are not limited thereto.

Bank patterns BNP may be disposed on the second alignment electrodes ELB. The bank patterns BNP may serve to form a step difference to readily align the light emitting elements LD. Each of the bank patterns BNP may be provided under at least one first alignment electrode ELA. As the bank patterns BNP are provided under one area of each of the first alignment electrodes ELA, one area of each of the first alignment electrodes ELA may be protruded in an upper direction, for example, in the third direction (Z-axis direction) of the sub-pixel SPX. In case that the bank patterns BNP and/or the first alignment electrodes ELA include a reflective material, a reflective wall structure may be formed around the light emitting elements LD. Accordingly, since light emitted from the light emitting elements LD may be emitted in the upper direction of the sub-pixel SPX (for example, a front surface direction of the display panel PNL including a viewing angle range), light output efficiency of the display panel PNL may be improved. However, a position of the bank patterns BNP is not limited thereto, and may be variously changed, such as under the second alignment electrodes ELB or on the first alignment electrodes ELA.

The bank patterns BNP may include at least one organic material and/or inorganic material. For example, the bank patterns BNP may include an organic material such as acrylates resin, epoxy resin, phenolic resin, polyamides resin, polyimides resin, polyester resin, polyphenylenesulfides resin, or benzocyclobutene (BCB). However, the disclosure is not limited thereto, and the bank patterns BNP may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A first insulating layer INS1 may be disposed on the bank patterns BNP. The first insulating layer INS1 may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The first alignment electrodes ELA may be disposed on the bank patterns BNP and the first insulating layer INS1. The first alignment electrodes ELA may be spaced apart from each other. The first alignment electrodes ELA may be disposed on the same layer. For example, the first alignment electrodes ELA may be simultaneously formed in the same process, but are not limited thereto.

The first alignment electrodes ELA may at least partially cover a side surface and/or an upper surface of the bank patterns BNP. The first alignment electrodes ELA may have a shape corresponding to the bank pattern BNP. For example, the first alignment electrodes ELA may include an inclined surface or a curved surface having a shape corresponding to the shape of the bank patterns BNP. In this case, since the bank patterns BNP and the first alignment electrodes ELA may reflect the light emitted from the light emitting elements LD as a reflective member to guide the light in a front surface direction of the sub-pixel SPX, for example, in the third direction (Z-axis direction), the light output efficiency of the display panel PNL may be improved.

The first alignment electrodes ELA may receive the first alignment signal in a position alignment step of the light emitting elements LD. Accordingly, an electric field may be formed between the first alignment electrodes ELA, and thus the light emitting elements LD provided to each of the sub-pixels SPX may be aligned in a space between the first alignment electrodes ELA.

The first alignment electrodes ELA may include at least one conductive material. For example, the first alignment electrodes ELA may include at least one conductive material among at least one metal among various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu), an alloy including the same, a conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but are not limited thereto.

A second insulating layer INS2 may be disposed on the first alignment electrodes ELA. The second insulating layer INS2 may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The light emitting elements LD may be disposed on the second insulating layer INS2. The light emitting elements LD may be disposed between the bank patterns BNP.

The light emitting elements LD may be prepared in a dispersed form in a light emitting element ink, and may be supplied to each of the sub-pixels SPX through an inkjet printing method or the like. For example, the light emitting elements LD may be dispersed in a volatile solvent and provided to each of the sub-pixels SPX. Subsequently, in case that the first alignment signal is supplied to the first alignment electrodes ELA, an electric field may be formed between the first alignment electrodes ELA, and thus the light emitting elements LD may be firstly aligned in a space between the first alignment electrodes ELA.

Subsequently, in case that the second alignment signal is supplied to the second alignment electrodes ELB, an electric field may be formed between the second alignment electrodes ELB, and thus the light emitting elements LD may be secondly aligned between the second alignment electrodes ELB. For example, the first end EP1 of the light emitting elements LD may face the first sub-alignment electrode ELB1. The second end EP2 of the light emitting elements LD may face the second sub-alignment electrode ELB2. The side portion SP between the first end EP1 and the second end EP2 of the light emitting elements LD may face the first alignment electrodes ELA. Since the position and the direction of the light emitting elements LD may be precisely controlled by aligning the position of the light emitting elements LD by using the first alignment electrodes ELA and aligning the direction of the light emitting elements LD by using the second alignment electrodes ELB as described above, the alignment degree of the light emitting elements LD may be improved. A detailed description thereof is described below with reference to FIGS. 16 to 21.

A third insulating layer INS3 may be disposed on the light emitting elements LD. For example, the second insulating layer INS2 may be partially provided on the light emitting elements LD and may expose the first and second ends EP1 and EP2 of the light emitting elements LD. When the third insulating layer INS3 is formed on the light emitting elements LD after alignment of the light emitting elements LD is completed, the light emitting elements LD may be prevented from being separated from an aligned position.

The third insulating layer INS3 may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The connection electrodes CNE may be disposed on the first and second ends EP1 and EP2 of the light emitting elements LD exposed by the third insulating layer INS3. The first connection electrode CNE1 may be directly disposed on the first end EP1 of the light emitting elements LD to be in contact with the first end EP1 of the light emitting elements LD. The second connection electrode CNE2 may be directly disposed on the second end EP2 of the light emitting elements LD to be in contact with the second end EP2 of the light emitting elements LD.

In an embodiment, the connection electrodes CNE may be formed of conductive layers. For example, as shown in FIG. 6, the first connection electrode CNE1 and the second connection electrode CNE2 may be formed of different conductive layers, and a fourth insulating layer INS4 may be formed between the first connection electrode CNE1 and the second connection electrode CNE2.

As described above, in case that the fourth insulating layer INS4 is disposed between the connection electrodes CNE formed of different conductive layers, since the connection electrodes CNE may be stably separated by the fourth insulating layer INS4, electrical stability between the first end EP1 and the second end EP2 of the light emitting elements LD may be secured.

The fourth insulating layer INS4 may be configured as a single layer or multiple layers, and may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

In another embodiment, the connection electrodes CNE may be formed of the same conductive layer. For example, as shown in FIG. 7, the first connection electrode CNE1 and the second connection electrode CNE2 may be formed of the same conductive layer. For example, the first connection electrode CNE1 and the second connection electrode CNE2 may be simultaneously formed in the same process. As described above, in case that the first connection electrode CNE1 and the second connection electrode CNE2 are simultaneously formed, the number of masks may be reduced and a manufacturing process may be simplified.

The connection electrodes CNE may be formed of various transparent conductive materials. For example, the connection electrodes CNE may include at least one of various transparent conductive materials including indium tin oxide (ITO), indium zinc oxide (IZO), indium tin zinc oxide (ITZO), aluminum zinc oxide (AZO), gallium zinc oxide (GZO), zinc tin oxide (ZTO), and gallium tin oxide (GTO), and may be implemented to be transparent or translucent to satisfy transmittance. Accordingly, light emitted from the ends EP1 and EP2 of the light emitting elements LD may pass through the connection electrodes CNE and may be emitted to an outside of the display panel PNL.

Hereinafter, another embodiment is described. In the following embodiment, the same configurations as those already described are referred to by the same reference numerals, and an overlapping content is omitted or briefly described.

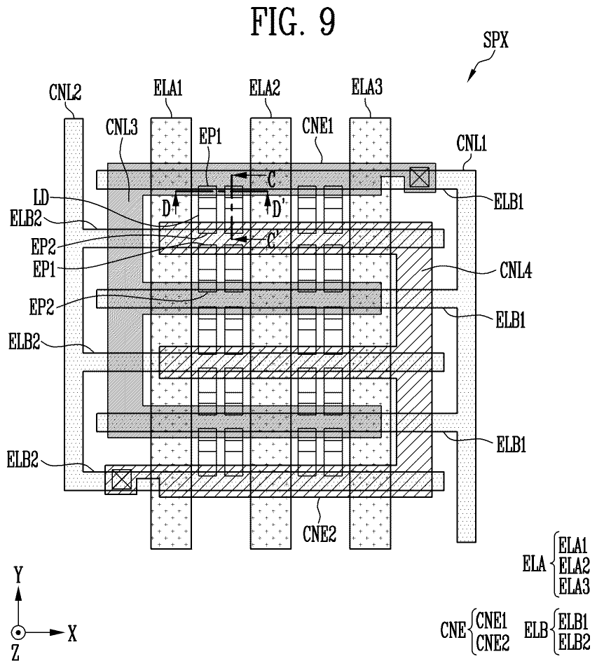

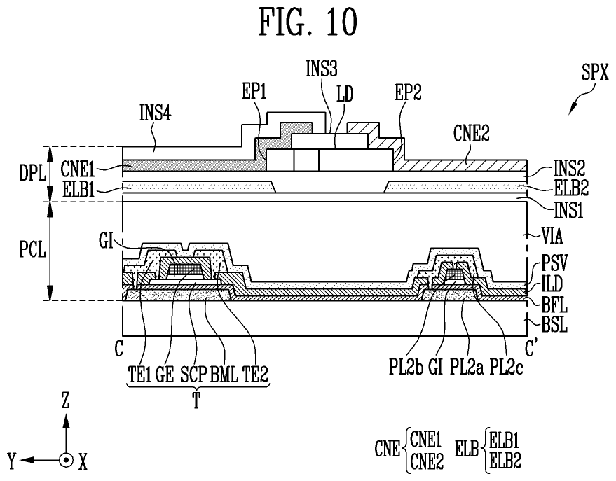

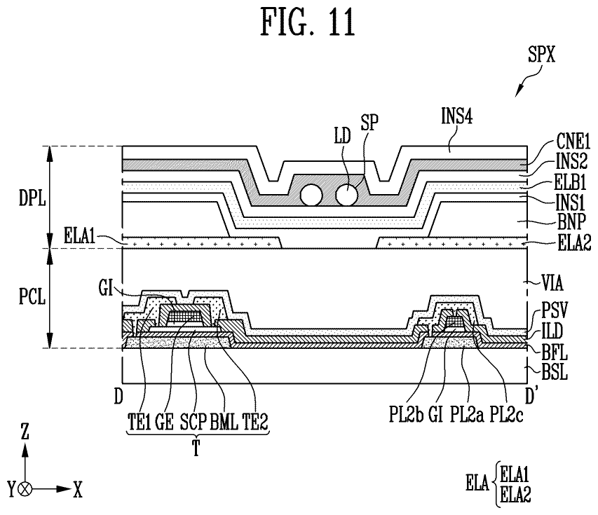

FIG. 9 is a schematic plan view illustrating a sub-pixel according to an embodiment. FIG. 10 is a schematic cross-sectional view taken along line C-C′ of FIG. 9. FIG. 11 is a schematic cross-sectional view taken along line D-D′ of FIG. 9.

Referring to FIGS. 9 to 11, the first alignment electrodes ELA may be disposed on the via layer VIA. The bank patterns BNP and the first insulating layer INS1 may be disposed on the first alignment electrodes ELA.

The second alignment electrodes ELB may be disposed on the bank patterns BNP and the first insulating layer INS1. The second alignment electrodes ELB may at least partially cover a side surface and/or an upper surface of the bank patterns BNP. The second alignment electrodes ELB may have a shape corresponding to the bank pattern BNP. For example, the second alignment electrodes ELB may include an inclined surface or a curved surface having a shape corresponding to a shape of the bank patterns BNP. In this case, since the bank patterns BNP and the second alignment electrodes ELB may reflect the light emitted from the light emitting elements LD as a reflective member to guide the light in the front surface direction, for example, the third direction (Z-axis direction) of the sub-pixel SPX, light output efficiency of the display panel PNL may be improved.

The second insulating layer INS2 may be disposed on the second alignment electrodes ELB. In an embodiment, the first connection electrode CNE1 may overlap the first sub-alignment electrode ELB1 and may be electrically connected to the first sub-alignment electrode ELB1 through a contact hole. The second connection electrode CNE2 may overlap the second sub-alignment electrode ELB2 and may be electrically connected to the second sub-alignment electrode ELB2 through a contact hole. The first connection electrode CNE1 may electrically connect the light emitting elements LD and the first sub-alignment electrode ELB1, and the second connection electrode CNE2 may electrically connect the light emitting elements LD and the second sub-alignment electrode ELB2. In this case, the first sub-alignment electrode ELB1 may be connected to the pixel circuit PXC and/or the first power line PL1 through a contact hole, and the second sub-alignment electrode ELB2 may be connected to the second power line PL2 through a contact hole, but the disclosure is not limited thereto.

According to an embodiment, the first connection electrode CNE1 may be electrically connected to the first sub-alignment electrode ELB1 through a first bridge electrode, and the second connection electrode CNE2 may be electrically connected to the second sub-alignment electrode ELB2 through a second bridge electrode.

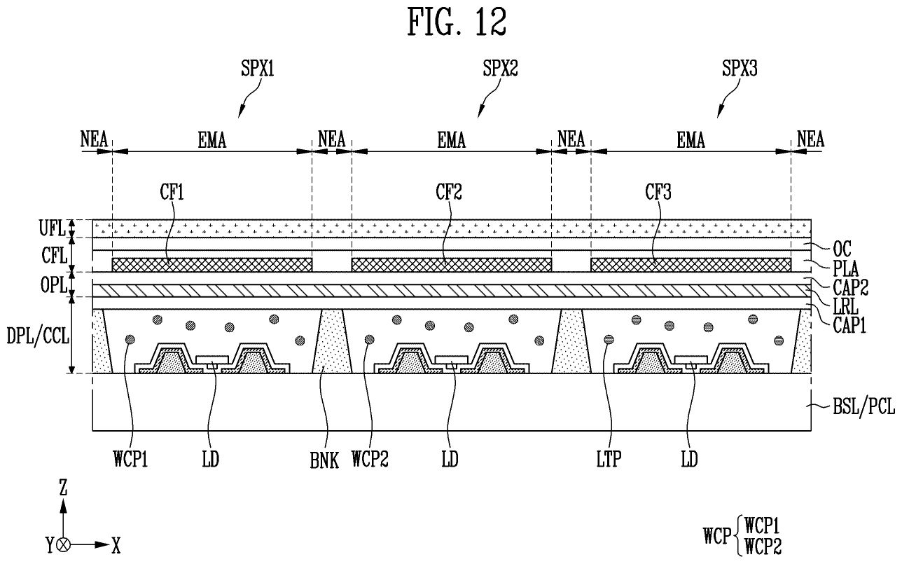

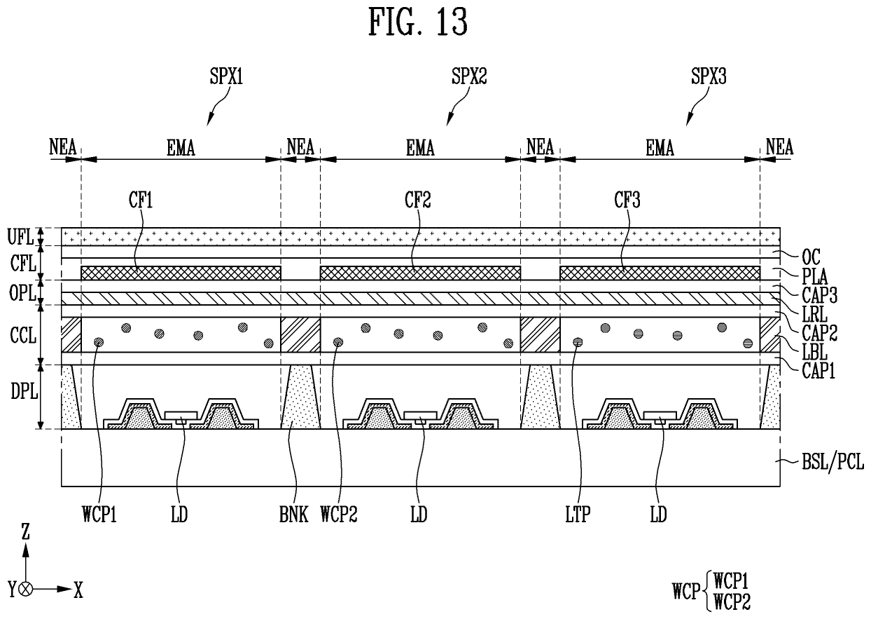

FIGS. 12 and 13 are schematic cross-sectional views illustrating a pixel unit according to an embodiment. For convenience of description, individual configurations of the pixel circuit layer PCL and the display element layer DPL are briefly expressed in FIGS. 12 and 13.

Referring to FIG. 12, the light emitting element LD disposed in each of the sub-pixels SPX1, SPX2, and SPX3 may emit light of the same color. For example, the sub-pixels SPX1, SPX2, and SPX3 may include a light emitting element LD that emits light of a third color, for example, blue light. A color conversion layer CCL and/or a color filter layer CFL may be provided in the sub-pixels SPX1, SPX2, and SPX3 to display a full-color of image. However, the disclosure is not limited thereto, and the sub-pixels SPX1, SPX2, and SPX3 may include light emitting elements LD that emit light of different colors.

As shown in FIG. 12, the color conversion layer CCL and the display element layer DPL may be disposed on the same layer. For example, the color conversion layer CCL may be disposed between banks BNK.

The bank BNK may be positioned in the non-emission area NEA of the sub-pixels SPX1, SPX2, and SPX3. The bank BNK may be formed between the sub-pixels SPX1, SPX2, and SPX3 to surround each emission area EMA. The bank BNK may include an opening overlapping the emission area EMA of each of the sub-pixels SPX1, SPX2, and SPX3. The bank BNK may function as a dam structure that prevents a solution for forming the color conversion layer CCL from flowing into the emission area EMA of the adjacent sub-pixels SPX1, SPX2, and SPX3, and/or that controls a constant amount of solution to be supplied to each emission area EMA.

The bank BNK may include an organic material or an inorganic material, and according to an embodiment, the bank BNK may include a black matrix material (or a light blocking material).

The color conversion layer CCL may include a first color conversion layer WCP1, a second color conversion layer WCP2, a light transmission layer LTP, and a first capping layer CAP1.

The first color conversion layer WCP1 may be disposed to overlap the emission area EMA of the first sub-pixel SPX1. The second color conversion layer WCP2 may be disposed to overlap the emission area EMA of the second sub-pixel SPX2. The light transmission layer LTP may be disposed to overlap the emission area EMA of the third sub-pixel SPX3. Each of the first color conversion layer WCP1, the second color conversion layer WCP2, and the light transmission layer LTP may be provided in the opening of the bank BNK overlapping the first to third sub-pixels SPX1, SPX2 and SPX3.

In an embodiment, the first color conversion layer WCP1 may include first color conversion particles that convert the light of the third color emitted from the light emitting element LD into the light of the first color. For example, in case that the light emitting element LD is a blue light emitting element emitting blue light and the first sub-pixel SPX1 is a red pixel, the first color conversion layer WCP1 may include a first quantum dot that converts the blue light emitted from the blue light emitting element into red light.

For example, the first color conversion layer WCP1 may include first quantum dots dispersed in a matrix material such as a base resin. The first quantum dot may absorb the blue light and shift a wavelength according to an energy transition to emit the red light. In case that the first sub-pixel SPX1 is a pixel of another color, the first color conversion layer WCP1 may include a first quantum dot corresponding to a color of the first sub-pixel SPX1.

In an embodiment, the second color conversion layer WCP2 may include second color conversion particles that convert the light of the third color emitted from the light emitting element LD into the light of the second color. For example, in case that the light emitting element LD is a blue light emitting element emitting blue light and the second sub pixel SPX2 is a green pixel, the second color conversion layer WCP2 may include a second quantum dot that converts the blue light emitted from the blue light emitting element into green light.

For example, the second color conversion layer WCP2 may include second quantum dots dispersed in a matrix material such as a base resin. The second quantum dot may absorb the blue light and shift a wavelength according to an energy transition to emit the green light.

The first quantum dot and the second quantum dot may have a shape of a spherical, pyramidal, multi-arm, or cubic nano particle, nano tube, nano wire, nano fiber, nano plate particle, or the like, but are not limited thereto, and a shape of the first quantum dot and the second quantum dot may be variously changed.

In an embodiment, an absorption coefficient of the first quantum dot and the second quantum dot may be increased by causing blue light having a relatively short wavelength in a visible light region to be incident on the first quantum dot and the second quantum dot. Accordingly, efficiency of light emitted from the first sub-pixel SPX1 and the second sub-pixel SPX2 may be increased, and excellent color reproducibility may be secured. Manufacturing efficiency of the display device may be increased by configuring the sub-pixel SPX by using the light emitting element LD of the same color (for example, the blue light emitting element).

In an embodiment, the light transmission layer LTP may be provided to efficiently use the light of the third color emitted from the light emitting element LD. For example, in case that the light emitting element LD is a blue light emitting element emitting blue light and the third sub-pixel SPX3 is a blue pixel, the light transmission layer LTP may include at least one type of light scattering particles to efficiently use the light emitted from the light emitting element LD.

For example, the light transmission layer LTP may include light scattering particles dispersed in a matrix material such as a base resin. For example, the light transmission layer LTP may include light scattering particles such as silica, but a configuration material of the light scattering particles is not limited thereto. According to an embodiment, the light scattering particles may also be included in the first color conversion layer WCP1 and/or the second color conversion layer WCP2.

A first capping layer CAP1 may seal (or cover) the first color conversion layer WCP1, the second color conversion layer WCP2, and the light transmission layer LTP. The first capping layer CAP1 may be disposed between a low refraction layer LRL and the display element layer DPL. The first capping layer CAP1 may be provided over the sub-pixels SPX1, SPX2, and SPX3. The first capping layer CAP1 may prevent an impurity such as moisture or air from permeating from the outside and damaging or contaminating the color conversion layer CCL.

In an embodiment, the first capping layer CAP1 may be configured as a single layer or multiple layers by including at least one insulating material among silicon oxide (SiOx), silicon nitride (SiNx), silicon oxynitride (SiOxNy), aluminum oxide (AlOx), and titanium oxide (TiOx), but is not limited thereto.

An optical layer OPL may include the low refraction layer LRL and a second capping layer CAP2. The optical layer OPL may be disposed on the color conversion layer CCL. The optical layer OPL may be disposed on the display element layer DPL.

The low refraction layer LRL may be disposed between the color conversion layer CCL and the color filter layer CFL. The low refraction layer LRL may be disposed between the first capping layer CAP1 and the second capping layer CAP2. The low refraction layer LRL may be provided over the sub-pixels SPX1, SPX2, and SPX3.

The low refraction layer LRL may serve to improve light efficiency by recycling light provided from the color conversion layer CCL by total reflection. To this end, the low refraction layer LRL may have a refractive index relatively lower than that of the color conversion layer CCL.

In an embodiment, the low refraction layer LRL may include a base resin and a hollow particle dispersed in the base resin. The hollow particle may include a hollow silica particle. As another example, the hollow particle may be a pore formed by porogen, but is not limited thereto. The low refraction layer LRL may include at least one of a zinc oxide (ZnO) particle, a titanium dioxide (TiO2) particle, and a nano silicate particle, but is not limited thereto.

The second capping layer CAP2 may be disposed on the low refraction layer LRL. The second capping layer CAP2 may be disposed between the color filter layer CFL and the low refraction layer LRL. The second capping layer CAP2 may be provided over the sub-pixels SPX1, SPX2, and SPX3. The second capping layer CAP2 may prevent an impurity such as moisture or air from permeating from the outside and damaging or contaminating the low refraction layer LRL. The second capping layer CAP2 and the first capping layer CPA1 may include the same material, or the second capping layer CAP2 may include one or more materials selected from the materials that may be used to form the first capping layer CPA1, e.g., as discussed herein. For example, the second capping layer CAP2 may be configured as a single layer or multiple layers by including at least one insulating material among silicon oxide (SiOx), silicon nitride (SiNx), silicon oxynitride (SiOxNy), aluminum oxide (AlOx), and titanium oxide (TiOx), but is not limited thereto.

The color filter layer CFL may be disposed on the second capping layer CAP2. The color filter layer CFL may be provided over the sub-pixels SPX1, SPX2, and SPX3. The color filter layer CFL may include color filters CF1, CF2, and CF3, a planarization layer PLA, and an overcoat layer OC.

In an embodiment, the color filters CF1, CF2, and CF3 may be disposed on the second capping layer CAP2. The color filters CF1, CF2, and CF3 may overlap the emission area EMA of the first to third sub-pixels SPX1, SPX2, and SPX3, respectively.

A first color filter CF1 may transmit the light of the first color, and may not transmit the light of the second color and the light of the third color. A second color filter CF2 may transmit the light of the second color, and may not transmit the light of the first color and the light of the third color. A third color filter CF3 may transmit the light of the third color, and may not transmit the light of the first color and the light of the second color.

In an embodiment, the planarization layer PLA may be disposed on the color filters CF1, CF2, and CF3. The planarization layer PLA may cover (or overlap) the color filters CF1, CF2, and CF3. The planarization layer PLA may planarize a step difference generated due to the color filters CF1, CF2, and CF3. The planarization layer PLA may be provided over the sub-pixels SPX1, SPX2, and SPX3.

The planarization layer PLA may include an organic material such as acrylates resin, epoxy resin, phenolic resin, polyamides resin, polyimides resin, polyester resin, polyphenylenesulfides resin, or benzocyclobutene (BCB). However, the disclosure is not limited thereto, and the planarization layer PLA may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The overcoat layer OC may be disposed on the planarization layer PLA. The overcoat layer OC may be disposed between an upper film layer UFL and the planarization layer PLA. The overcoat layer OC may be provided over the sub-pixels SPX1, SPX2, and SPX3. The overcoat layer OC may cover a lower member including the color filter layer CFL. The overcoat layer OC may prevent moisture or air from permeating into the above-described lower member. The overcoat layer OC may protect the above-described lower member from a foreign substance such as dust.

The overcoat layer OC may include an organic material or an inorganic material. For example, the overcoat layer OC may include one or more materials selected from the materials that may be used to form the planarization layer PLA, e.g., as discussed herein.

The upper film layer UFL may be disposed on the color filter layer CFL. The upper film layer UFL may be disposed outside the display device to reduce external influence on the display device. The upper film layer UFL may be provided over the sub-pixels SPX1, SPX2, and SPX3.

In an embodiment, the upper film layer UFL may include an AR coating layer (anti-reflective coating). The AR coating layer may refer to a configuration in which a material having an anti-reflection function is applied to one surface of a specific configuration. Here, the applied material may have a low reflectance. For example, the material used for the AR coating layer may include any one of silicon oxide (SiOx), aluminum oxide (AlOx), and titanium oxide (TiOx), but is not limited thereto.

In another embodiment, the color conversion layer CCL may be disposed on the display element layer DPL as shown in FIG. 13. For example, the first capping layer CAP1 may seal (or cover) an area in which the light emitting elements LD are disposed, and the color conversion layer CCL may be disposed on the first capping layer CAP1.

In an embodiment, the color conversion layer CCL may further include a light blocking layer LBL (or a light blocking pattern). The light blocking layer LBL may be disposed on the display element layer DPL. The light blocking layer LBL may be disposed between the first capping layer CAP1 and the second capping layer CAP2. The light blocking layer LBL may be disposed to surround the first color conversion layer WCP1, the second color conversion layer WCP2, and the light transmission layer LTP at a boundary between the sub-pixels SPX1, SPX2, and SPX3.

The light blocking layer LBL may overlap the non-emission area NEA. The light blocking layer LBL may surround the emission area EMA of the sub-pixels SPX1, SPX2, and SPX3. The light blocking layer LBL may be formed of an organic material including at least any one of graphite, carbon black, black pigment, or black dye, or may be formed of a metal material including chromium (Cr), but is not limited as long as the light blocking layer LBL is a material capable of blocking and absorbing light.

The second capping layer CAP2 may seal (or cover) the first color conversion layer WCP1, the second color conversion layer WCP2, and the light transmission layer LTP.

The low refraction layer LRL may be disposed between the second capping layer CAP2 and a third capping layer CAP3. The third capping layer CAP3 may include the same material as the first capping layer CPA1 or may include one or more materials selected from the materials that may be used to form the first capping layer CPA1, e.g., as discussed herein.

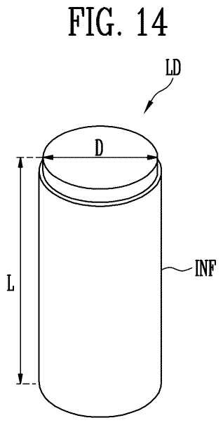

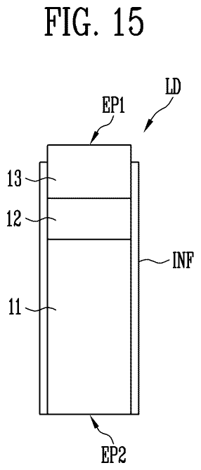

FIG. 14 is a schematic perspective view illustrating a light emitting element according to an embodiment. FIG. 15 is a schematic cross-sectional view illustrating a light emitting element according to an embodiment. FIGS. 14 and 15 show a column shape of light emitting element LD, but a type and/or a shape of the light emitting element LD are/is not limited thereto.

Referring to FIGS. 14 and 15, the light emitting element LD may include a first semiconductor layer 11, a second semiconductor layer 13, and an active layer 12 interposed between the first and second semiconductor layers 11 and 13. For example, in case that an extension direction of the light emitting element LD is a length L direction, the light emitting element LD may include the first semiconductor layer 11, the active layer 12, and the second semiconductor layer 13 sequentially stacked along the length L direction.

The light emitting element LD may be provided in a column shape extending along a direction. The light emitting element LD may have a first end EP1 and a second end EP2. One of the first and second semiconductor layers 11 and 13 may be disposed at the first end EP1 of the light emitting element LD. The other of the first and second semiconductor layers 11 and 13 may be disposed at the second end EP2 of the light emitting element LD.

According to an embodiment, the light emitting element LD may be a light emitting element manufactured in a column shape through an etching method or the like. In the specification, the column shape includes a rod-like shape or a bar-like shape that is long in the length L direction (for example, an aspect ratio is greater than 1), such as a circular column or a polygonal column, and a shape of a cross-section thereof is not particularly limited. For example, a length L of the light emitting element LD may be greater than a diameter D (or a width of a cross section).

The light emitting element LD may have a size as small as a nanometer scale to a micrometer scale. For example, each light emitting element LD may have the diameter D (or width) and/or the length L of a nanometer scale to micrometer scale range. However, a size of the light emitting element LD is not limited thereto, and the size of the light emitting element LD may be variously changed according to a design condition of various devices by using a light emitting device that uses the light emitting element LD as a light source, for example, a display device.

The first semiconductor layer 11 may be a semiconductor layer of a first conductivity type. For example, the first semiconductor layer 11 may include an n-type semiconductor layer. For example, the first semiconductor layer 11 may include any one semiconductor material among InAlGaN, GaN, AlGaN, InGaN, AlN, and InN, and may include an n-type semiconductor layer doped with a first conductivity type dopant such as Si, Ge, and Sn. However, a material configuring the first semiconductor layer 11 is not limited thereto, and various other materials may configure the first semiconductor layer 11.

The active layer 12 may be disposed on the first semiconductor layer 11 and may be formed in a single quantum well or multi-quantum well structure. A position of the active layer 12 may be variously changed according to the type of the light emitting element LD.

A clad layer (not shown) doped with a conductive dopant may be formed on and/or under the active layer 12. For example, the clad layer may be formed of AlGaN or InAlGaN. According to an embodiment, a material of AlGaN, InAlGaN, or the like may be used to form the active layer 12, and various other materials may configure the active layer 12.

The second semiconductor layer 13 may be disposed on the active layer 12 and may include a semiconductor layer of a type different from that of the first semiconductor layer 11. For example, the second semiconductor layer 13 may include a p-type semiconductor layer. For example, the second semiconductor layer 13 may include at least one semiconductor material among InAlGaN, GaN, AlGaN, InGaN, AlN, and InN, and may include a p-type semiconductor layer doped with a second conductivity type dopant such as Mg. However, a material configuring the second semiconductor layer 13 is not limited thereto, and various other materials may configure the second semiconductor layer 13.

In case that a voltage equal to or greater than a threshold voltage is applied to both ends of the light emitting element LD, an electron-hole pair is combined in the active layer 12, and thus the light emitting element LD emits light. By controlling light emission of the light emitting element LD by using such a principle, the light emitting element LD may be used as a light source of various light emitting devices including a pixel of a display device.

The light emitting element LD may further include an insulating film INF provided on a surface. The insulating film INF may be formed on the surface of the light emitting element LD to surround an outer circumferential surface of at least active layer 12, and may further surround one region of the first and second semiconductor layers 11 and 13.

According to an embodiment, the insulating film INF may expose the ends (e.g., both ends) of the light emitting element LD having different polarities. For example, the insulating film INF may expose an end of each of the first and second semiconductor layers 11 and 13 positioned at the first and second ends EP1 and EP2 of the light emitting element LD. In another embodiment, the insulating film INF may expose a side portion of the first and second semiconductor layers 11 and 13 adjacent to the first and second ends EP1 and EP2 of the light emitting element LD having different polarities.

According to an embodiment, the insulating film INF may include at least one insulating material among silicon oxide (SiOx), silicon nitride (SiNx), silicon oxynitride (SiOxNy), aluminum oxide (AlOx), and titanium oxide (TiOx), and may be configured as a single layer or multiple layers (for example, a double layer formed of aluminum oxide (AlOx) and silicon oxide (SiOx)), but is not limited thereto. According to an embodiment, the insulating film INF may be omitted.

In case that the insulating film INF is provided to cover the surface of the light emitting element LD, in particular, the outer circumferential surface of the active layer 12, a short between the active layer 12, and an electrode, or the like to be described below may be prevented. Accordingly, electrical stability of the light emitting element LD may be secured.

In case that the insulating film INF is provided on the surface of the light emitting element LD, a surface defect of the light emitting element LD may be minimized, thereby improving life and efficiency. In addition, also in a case where light emitting elements LD are disposed in close contact with each other, an unwanted short between the light emitting elements LD may be prevented.

In an embodiment, the light emitting element LD may further include an additional component in addition to the first semiconductor layer 11, the active layer 12, the second semiconductor layer 13, and/or the insulating film INF surrounding them. For example, the light emitting element LD may further include at least one phosphor layer, active layer, semiconductor layer, and/or electrode layer disposed on one end side of the first semiconductor layer 11 and/or the second semiconductor layer 13. For example, a contact electrode layer may be disposed at each of the first and second ends EP1 and EP2 of the light emitting element LD. Although the column shape light emitting element LD is illustrated as an example in FIG. 15, a type, a structure, a shape, and/or the like of the light emitting element LD may be variously changed. For example, the light emitting element LD may be formed in a core-shell structure having a polygonal cone shape.

A light emitting device including the light emitting element LD described above may be used in various types of devices that require a light source, including a display device. For example, the light emitting elements LD may be disposed in each sub-pixel SPX of the above-described display panel PNL, and the light emitting elements LD may be used as a light source of each sub-pixel SPX. However, an application field of the light emitting element LD is not limited to the above-described example. For example, the light emitting element LD may also be used in other types of devices that require a light source, such as a lighting device.

Subsequently, a method of manufacturing the display device according to the above-described embodiments is described.

FIGS. 16 to 21 are schematic plan views for each process step of a method of manufacturing a display device according to an embodiment. FIGS. 16 to 21 schematically show a planar structure based on the first alignment line ELA1 (or the first electrode) and the second alignment line ELA2 (or the second electrode) of the first alignment electrode ELA of FIG. 4 and the first sub-alignment electrode ELB1 (or the third electrode) and the second sub-alignment electrode ELB2 (or the fourth electrode). Hereinafter, components substantially the same as those of FIGS. 1 to 15 are denoted by the same reference numerals, and detailed reference numerals are omitted.

Referring to FIG. 16, the first alignment electrodes ELA and the second alignment electrodes ELB crossing each other are formed. The first alignment electrodes ELA may extend in the second direction (Y-axis direction) and may be spaced apart from each other in the first direction (X-axis direction). The second alignment electrodes ELB may extend in the first direction (X-axis direction) and may be spaced apart from each other in the second direction (Y-axis direction). As described with reference to FIGS. 6 to 8, the first alignment electrodes ELA may be formed on the second alignment electrodes ELB. As another example, as described with reference to FIGS. 10 and 11, the second alignment electrodes ELB may be formed on the first alignment electrodes ELA.

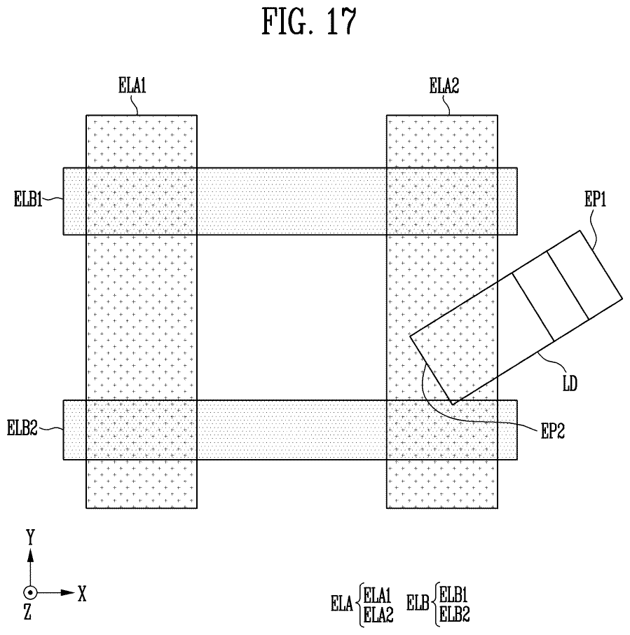

Referring to FIG. 17, subsequently, the light emitting elements LD are provided. The light emitting elements LD may be prepared in a dispersed form in the light emitting element ink, and may be supplied through an inkjet printing method or the like. For example, the light emitting elements LD may be dispersed in a volatile solvent and provided.

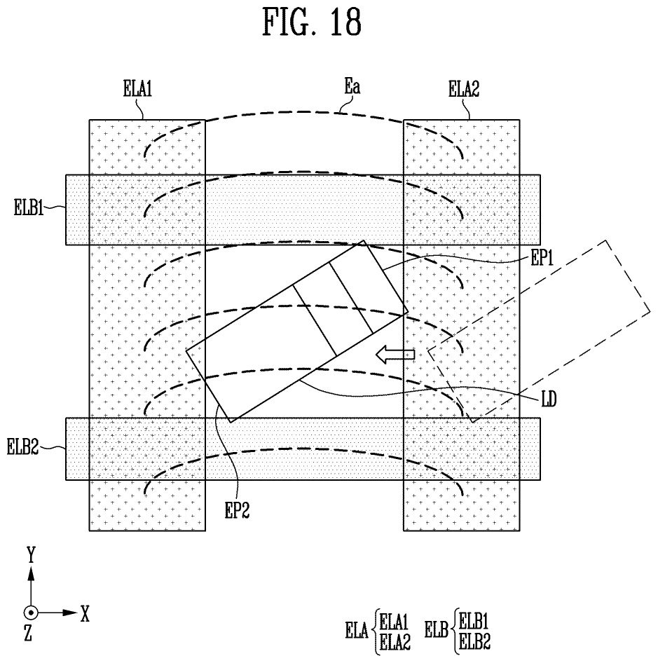

Referring to FIG. 18, the position of the light emitting elements LD are firstly aligned. The first alignment signal may be applied to the first alignment electrodes ELA to align the position of the light emitting elements LD. In case that the first alignment signal is applied to the first alignment electrodes ELA, an electric field Ea may be formed between the first alignment electrodes ELA, and thus the light emitting elements LD may move to a space between the first alignment electrodes ELA.

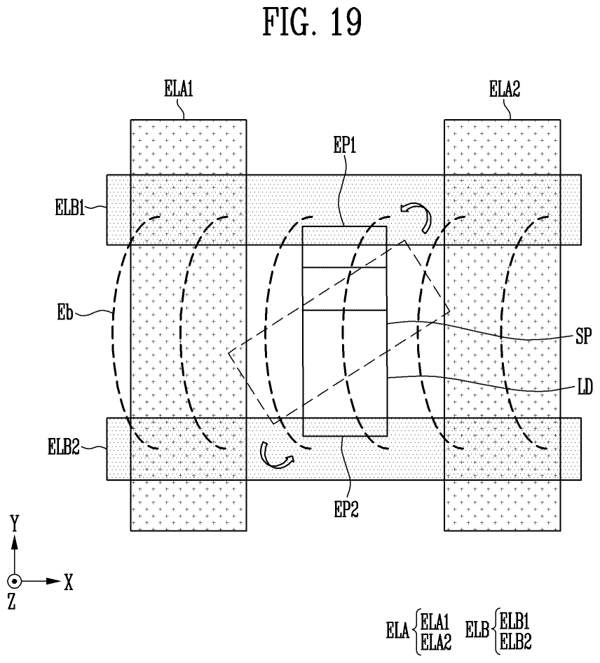

Referring to FIG. 19, subsequently, the direction of the light emitting elements LD are secondly aligned. The second alignment signal may be applied to the second alignment electrodes ELB to align the direction of the light emitting elements LD. In case that the second alignment signal is applied to the second alignment electrodes ELB, an electric field Eb may be formed between the second alignment electrodes ELB, and thus the light emitting elements LD may be biasedly aligned. The light emitting elements LD may be biasedly aligned so that the first end EP1 faces the first sub-alignment electrode ELB1, the second end EP2 faces the second sub-alignment electrode ELB2, and the side portion SP between the first end EP1 and the second end EP2 face the first alignment electrodes ELA. In an embodiment, the frequency of the second alignment signal and the frequency of the first alignment signal may be different from each other, but is not limited thereto.

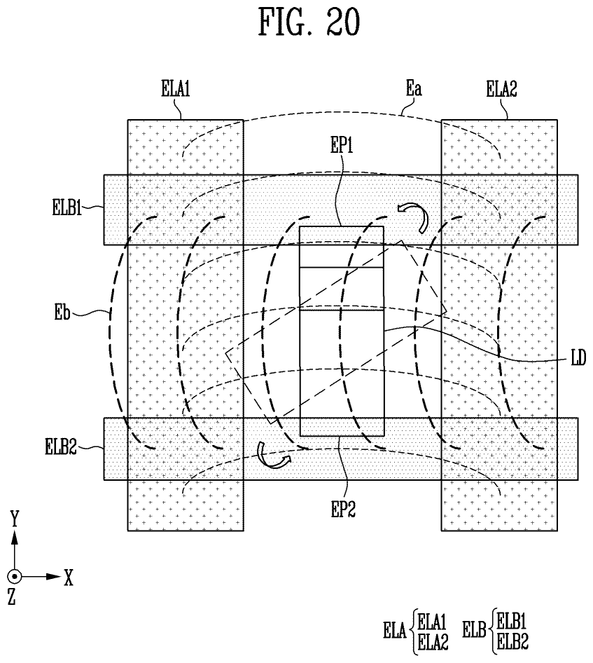

According to an embodiment, as shown in FIG. 20, the first alignment signal may be applied to the first alignment electrodes ELA in a process of secondly aligning the light emitting elements LD. Accordingly, the light emitting elements LD may be biasedly aligned while maintaining the position of the firstly aligned light emitting elements LD. In this case, the first alignment signal may be applied to the first alignment electrodes ELA by adjusting an intensity of the first alignment signal.

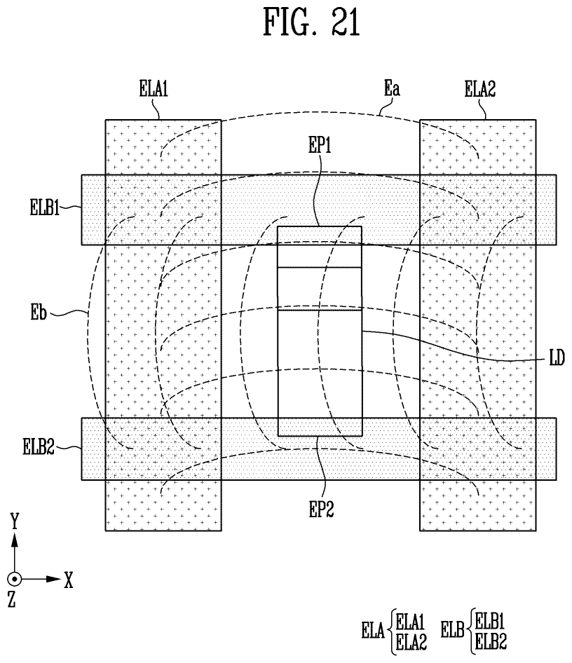

Referring to FIG. 21, the position and the direction of the light emitting elements LD are thirdly aligned. The first alignment signal may be applied to the first alignment electrodes ELA and the second alignment signal may be applied to the second alignment electrodes ELB in order to stably maintain the position and the direction of the light emitting elements LD. In this case, the first alignment signal and the second alignment signal may be applied and then the application of the first alignment signal and the second alignment signal may be stopped at a constant time interval by adjusting intensities of the first alignment signal and the second alignment signal. According to an embodiment, the third alignment step may be omitted, and the first alignment step or the second alignment step may be repeated according to the alignment degree of the light emitting elements LD. Subsequently, the light emitting elements LD may be stably arranged by volatilizing or removing the solvent in another method.

Subsequently, the display device may be completed by forming connection electrodes CNE or the like on the light emitting elements LD. According to an embodiment, each of the connection electrodes CNE may be electrically connected to at least one of the first alignment electrodes ELA, as described with reference to FIGS. 4 and 5. As another example, as described with reference to FIG. 9, each of the connection electrodes CNE may be electrically connected to at least one of the second alignment electrodes ELB.

According to the above-described embodiment, since the position and the direction of the light emitting elements LD may be precisely controlled by aligning the position of the light emitting elements LD by using the first alignment electrodes ELA and aligning the direction of the light emitting elements LD by using the second alignment electrodes ELB, the alignment degree of the light emitting elements LD may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode and a second electrode spaced apart from each other;
a third electrode and a fourth electrode intersecting the first and second electrodes and spaced apart from each other; and
light emitting elements disposed between the first and second electrodes, wherein
a first end of each of the light emitting elements faces the third electrode, and
a second end of each of the light emitting elements faces the fourth electrode.

2. The display device according to claim 1, wherein
the first and second electrodes are spaced apart from each other in a first direction and extend in a second direction, and
the third and fourth electrodes are spaced apart from each other in the second direction and extend in the first direction.

3. The display device according to claim 2, wherein the light emitting elements are arranged in the second direction.

4. The display device according to claim 1, wherein the first and second electrodes are disposed on the third and fourth electrodes.

5. The display device according to claim 4, further comprising:
an insulating layer between the first and second electrodes and the third and fourth electrodes.

6. The display device according to claim 4, further comprising:
a first connection electrode that is in electrical contact with the first end of each of the light emitting elements; and
a second connection electrode that is in electrical contact with the second end of each of the light emitting elements.

7. The display device according to claim 6, wherein
the first connection electrode is electrically connected to the first electrode, and
the second connection electrode is electrically connected to the second electrode.

8. The display device according to claim 1, wherein the third and fourth electrodes are disposed on the first and second electrodes.

9. The display device according to claim 8, wherein the light emitting elements are electrically connected to the third and fourth electrodes.

10. The display device according to claim 1, wherein a side portion between the first end and the second end of each of the light emitting elements faces the first and second electrodes.

11. A method of manufacturing a display device, the method comprising:
firstly aligning light emitting elements between first alignment electrodes by applying a first alignment signal to the first alignment electrodes; and
secondly aligning the light emitting elements by applying a second alignment signal to second alignment electrodes crossing the first alignment electrodes, wherein
the second alignment electrodes extend in a first direction and are spaced apart from each other in a second direction, and
the light emitting elements are aligned in the second direction in the secondly aligning of the light emitting elements.

12. The method according to claim 11, wherein a frequency of the first alignment signal is different from a frequency of the second alignment signal.

13. The method according to claim 11, wherein
the second alignment electrodes include a first sub-alignment electrode and a second sub-alignment electrode spaced apart from each other in the second direction,
a first end of each of the light emitting elements faces the first sub-alignment electrode, and
a second end of each of the light emitting elements faces the second sub-alignment electrode.

14. The method according to claim 13, wherein the first and second sub-alignment electrodes are alternately arranged in the second direction.

15. The method according to claim 13, wherein a side portion between the first end and the second end of each of the light emitting elements faces the first alignment electrodes.

16. The method according to claim 11, further comprising:
forming connection electrodes on the light emitting elements.

17. The method according to claim 16, wherein the connection electrodes are electrically connected to the first alignment electrodes.

18. The method according to claim 17, wherein the first alignment electrodes are formed on the second alignment electrodes.

19. The method according to claim 16, wherein the connection electrodes are electrically connected to the second alignment electrodes.

20. The method according to claim 19, wherein the second alignment electrodes are formed on the first alignment electrodes.
